(19) United States
(12) Patent Application Publication
(10) Pub. No.: US 2009/0091008 A1
(43) Pub. Date: Apr. 9, 2009

(54) Semiconductor device

(76) Inventor: Toshihiko Mizukami, Osaka (JP)

Correspondence Address: KUBOTERA & ASSOCIATES. LLC, Suite 202, 200 Daingerfield Road, Alexandria, VA, 22314, US

(21) Appl. No.: 12/292,798

(22) Filed: Nov. 26, 2008

Related U.S. Application Data
(63) Continuation of application No. PCT/JP2007/060958, filed on May 30, 2007.

(30) Foreign Application Priority Data
May 31, 2006 (JP) 2006-151473

(51) Int. Cl. H01L 23/495

(52) U.S. Cl. 257/666; 257/E23.031

(57) ABSTRACT

A semiconductor device for programmable logic or operation processing includes a semiconductor chip; a first connecting terminal for electrically connecting the semiconductor device to a printed circuit board on which the semiconductor device is to be mounted; a second connecting terminal for electrically connecting the semiconductor device to another semiconductor device; and a packaging material for sealing the semiconductor chip, the first connecting terminal, and the second connecting terminal. Then, the first connecting terminal is formed of the lead frame, and the second connecting terminal is formed on the wiring board.

### CROSS-REFERENCE TO RELATED APPLICATION

This is a continuation application of the prior PCT application PCT/JP2007/060958, filed on May 30, 2007, which is claiming the priority of Japanese Patent Application No. 2006-151473, filed on May 31, 2006.

### BACKGROUND OF THE INVENTION AND RELATED ART STATEMENT

The present invention relates to a semiconductor device using a MCP (Multi-Chip Package) in which two or more semiconductor chips with different features are integrated into one package.

Recently, a semiconductor process and a circuit element for particular applications are used in various fields, with high function and high performance of LSI (Large Scale Integration). As a result, SOC (System On Chip), with which an entire system is constructed by using LSI, progresses greatly to achieve high-density mounting and cost reduction.

However, for development of SOC achieving the various functions and performance that are necessary for a system with the one tip, it is necessary for a great investment and a long cycle for the development, because it is necessary to realize for the one tip, using the various circuits where the most suitable processes are different, in other words, using the circuit that conflicts in the performance, the quality, and the cost, for instance, mixture of analog circuit and digital circuit, mixture of high-speed circuit and low-speed circuit, mixture of high withstand pressure circuit and low withstand pressure circuit, mixture of high power circuit and low power circuit, and mixture of custom circuit and general-purpose circuit (for instance, CPU, DSP, DRAM, Flash memory, power supply, driver, custom LSI, analog IC, and electronic parts, etc).

As a means to solve the above problem, the semiconductor device of the MCP structure is used for many varieties and small amount production. Therefore, the semiconductor device of various MCP structures is proposed.

For instance, “Patent document 1” discloses a semiconductor device of the chip-on-chip structure, which has a characteristic that two or more semiconductor chips are joined to two levels of layered structures, with overlapping two or more semiconductor chips in condition that the surface of the semiconductor chip opposes it mutually. In this invention, it is characterized that the insulating film with which the wiring pattern provided beforehand is formed is prepared, and the first semiconductor chip and the second semiconductor chip are overlapped like doing the above-mentioned insulating film in the sandwich. Therefore, this invention enables to overlap the semiconductor chips with a different electrode arrangement pitch mutually and to connect them.

“Patent document 2” discloses a semiconductor module, which has a characteristic that two or more boards are mutually overlapped in condition that boards are mutually connected with flexible cables, and a semiconductor chip is mounted respectively on face of boards mutually opposed, and the above-mentioned semiconductor chips are mutually bonded to them, and a external terminal for connecting to a mother board is formed on the board arranged in the outermost layer. This invention enables to make the interval between boards a minimum without contact directly between semiconductor chips, and mount the semiconductor module on the motherboard with the external terminal formed on the board arranged in the outermost layer.

“Patent document 3” discloses a semiconductor device, which has a characteristic of comprising: a package board with which two or more wirings are formed on both sides; a semiconductor chip which is mounted on the one side of the package board, and is electrically connected to the wirings formed on the one side; a resin for sealing with which the semiconductor chip and a part of the above-mentioned wirings are covered; a reinforcement frame which is formed along surroundings edge of the other side of the package board; two or more bumps which are electrically connected to the wirings formed on the one side of the package board; a through hall wiring with which the wirings formed on the one side and the wirings formed on the other side are electrically connected through a through hall; and a land part which is mounted on the other side of the package board. This invention provides the small and thin semiconductor device for FBGA (Fine-pitch Ball Grid Array), which mounts devices in the laminated structure. That is, this invention enables to mount two or more semiconductor chips on the land part, to make to high density in direction of two dimensions, and to make to high density in direction of three dimensions.

“Patent document 4” discloses a semiconductor device, which has a characteristic that the first semiconductor chip is mounted on the one side of the package board, and the second semiconductor chip is mounted on the other side of the package board, on which the outer-lead part is mounted. This invention enables to improve the mounting efficiency of the semiconductor device, and to decrease the occupation area of the semiconductor device to the same level as CSP (Chip Scale Package), because the first semiconductor chip and the second semiconductor chip are mounted on the both sides of the package board. Also, this invention enables to shorten the wiring distance between the first semiconductor chip and the second semiconductor chip, because the first semiconductor chip and the second semiconductor chip are approximated through the package board. As a result, the performance of the semiconductor device will be improved.

“Patent document 5” discloses a semiconductor device, which has a characteristic that two or more semiconductor chips are mounted in the laminated structure, because the second semiconductor chip, on which the projection-electrode is formed, is set up at opposite of the first semiconductor chip, and the above projection-electrode is electrically connected to the electrode of the first semiconductor chip. This invention enables to mount semiconductor chips with various shapes in the laminated structure, without restriction shapes of each semiconductor chips.

“Patent document 6” discloses a semiconductor device, which has a characteristic that the first semiconductor chip is connected to the first electro-conductive-trace on the one side of the wiring board, wherein the first package frame is formed around the first semiconductor chip and a part of the first trace, and the second semiconductor chip is connected to the second trace on the other side of the wiring board, wherein the second package frame is formed around the second semiconductor chip and a part of the second trace. Here, solder balls, which are connected to exposed part of the second trace, supply an external voltage to each semiconductor devices, and establish a grand connection. This invention enables to achieve the multi-chip modulation at a low price, without increase the packaging size of the semiconductor device. Also, this invention enables to provide, at a low price, the small multi-chip semiconductor device with over-molding type.

“Patent document 7” discloses a multi-chip package, which has a characteristic that the multi-chip package comprises two or more accumulating packages composed of the upper-package and the below-package, which comprise: a connecting board on which the pocket opened to center and wiring patterns are formed; one or two or more semiconductor chips which are mounted on the connecting board; two or more wiring patterns which are formed on the connecting board; and two or more bonding wires with which the bonding Pad and the Pad formed on the connecting board are connected, wherein the connecting board of the upper-package is connected to the below-package. This invention enables to provide the accumulating package, which mounts semiconductor chips desired with accumulating, and is made thin.

“Patent document 8” discloses a multi-chip package, which has a characteristic that the multi-chip package comprises: a wiring board on which two or more bonding Pads are formed; the first semiconductor chip which is mounted on the wiring board; and the second semiconductor chip which is mounted on the wiring board. This invention enables to provide the multi-chip package, which has enough space (three dimension space) to mount the semiconductor chip arranged below, if the semiconductor chip arranged upper is very large compared with the semiconductor chip arranged below. Also, this invention enables to isolate the semiconductor chip arranged below from the semiconductor chip arranged upper, and to prevent each other being interfered.

Patent document 1: Japanese Patent Publication No. 2000-252408
Patent document 2: Japanese Patent Publication No. 2003-133518
Patent document 3: Japanese Patent Publication No. 2000-243867
Patent document 4: Japanese Patent Publication No. 10-284544
Patent document 5: Japanese Patent Publication No. 08-125112
Patent document 6: Japanese Patent Publication No. 06-077398
Patent document 7: Japanese Patent Publication No. 2005-005709
Patent document 8: Japanese Patent Publication No. 2005-203776

However, in the above-mentioned semiconductor device of past MCP structure, there is a problem that it is necessary to develop the semiconductor chip only for MCP, and it takes time when a special package is developed, that is, it is necessary for the period and the workload equal with the development of a general-purpose semiconductor device. In addition, there is a problem that the price is remarkably high compared with SOC. Also, there is a problem that it is not possible to connect or exchange the desired semiconductor chip after the package has been sealed. Also, there is a problem that a general-purpose semiconductor device cannot be used for the semiconductor device of the MCP structure, because it is necessary to compose the semiconductor device of the MCP structure by the semiconductor chip. In addition, there is a problem that, when the circuit is composed of some general-purpose semiconductor devices, the mounting area of the circuit grows by increasing of the semiconductor device, and the wiring distance between semiconductor devices becomes long by increasing of the semiconductor device, as a result, deterioration of an electric signal is caused, and unnecessary radiation increases, and power consumption increases, because of increase of parasitic capacitance of wiring, increase of coil element and resistance element, and mixing of noise.

Also, in “Patent document 3”, there is a problem that, when two or more semiconductor devices are accumulated after the package has been sealed, the best miniaturization of the package size is difficult, because it is necessary to set up the land part, which connects the printed wiring board such as motherboard, in the outer part of the semiconductor chip.

The present invention proposes a solution to the above problem. The present invention aims to disclose the technology to easily provide the semiconductor device of the MCP structure using the general-purpose semiconductor device, for great shortening of development period and cost reduction of development investment. Also, the present invention aims to disclose the technology to enable to freely mount (or, change) the semiconductor chip or the semiconductor device after the MCP package has been sealed.

Also, the present invention enables to minimize the mounting area of the circuit using the general-purpose semiconductor device, and to make the wiring distance between semiconductor devices the shortest. As a result, the present invention achieves to secure the quality and the performance of an electric signal, to decrease power consumption, and to decrease an unnecessary radiation.

### SUMMARY OF THE INVENTION

To achieve the above target, according to a first aspect of the present invention, a semiconductor device for programmable logic or operation processing comprises:

a semiconductor chip;

a first connecting terminal for electrically connecting the semiconductor device to a printed circuit board on which the semiconductor device is mounted;

a second connecting terminal for electrically connecting the semiconductor device to another semiconductor device; and

a packaging material for sealing the semiconductor chip, the first connecting terminal, and the second connecting terminal;

wherein the first connecting terminal is formed on a first wiring board, and the second connecting terminal is formed on a second wiring board.

As clarified above, the present invention enables to easily provide the semiconductor device of the MCP structure, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because it is possible to use a general-purpose semiconductor device for another semiconductor device described above.

According to a second aspect of the present invention, a semiconductor device for programmable logic or operation processing comprises:

a semiconductor chip;

a first connecting terminal for electrically connecting the semiconductor device to a printed circuit board on which the semiconductor device is to be mounted;

a second connecting terminal for electrically connecting the semiconductor device to another semiconductor device; and

a packaging material for sealing the semiconductor chip, the first connecting terminal, and the second connecting-terminal;

wherein the first connecting terminal is formed of a first lead frame, and the second connecting terminal is formed of a second lead frame.

As clarified above, the present invention enables to easily provide the semiconductor device of the MCP structure, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because it is possible to use a general-purpose semiconductor device for another semiconductor device described above, and because the first connecting terminal and the second connecting terminal are composed of the lead frame.

According to a third aspect of the present invention, a semiconductor device for programmable logic or operation processing comprises:

a semiconductor chip;

a first connecting terminal for electrically connecting the semiconductor device to a printed circuit board on which the semiconductor device is mounted;

a second connecting terminal for electrically connecting the semiconductor device to another semiconductor device; and

a packaging material for sealing the semiconductor chip, the first connecting terminal, and the second connecting terminal;

wherein the first connecting terminal is formed of a first lead frame, and the second connecting terminal is formed on a second wiring board.

As clarified above, the present invention enables to easily provide the semiconductor device of the MCP structure, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because it is possible to use a general-purpose semiconductor device for another semiconductor device described above, and because the first connecting terminal is composed of the lead frame.

According to a fourth aspect of the present invention, a semiconductor device for programmable logic or operation processing comprises:

a semiconductor chip;

a first connecting terminal for electrically connecting the semiconductor device to a printed circuit board on which the semiconductor device is mounted;

a second connecting terminal for electrically connecting the semiconductor device to another semiconductor device; and

a packaging material for sealing the semiconductor chip, the first connecting terminal, and the second connecting terminal;

wherein the first connecting terminal is formed on a first wiring board, and the second connecting terminal is formed of a second lead frame.

As clarified above, the present invention enables to easily provide the semiconductor device of the MCP structure, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit using by the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because it is possible to use a general-purpose semiconductor device for another semiconductor device described above, and because the second connecting terminal is composed of the lead frame.

According to a fifth aspect of the present invention, a semiconductor device for programmable logic or operation processing comprises:

a semiconductor chip;

a first connecting terminal for electrically connecting the semiconductor device to a printed circuit board on which the semiconductor device is mounted;

a second connecting terminal for electrically connecting the semiconductor device to another semiconductor device;

a packaging material for sealing the semiconductor chip, the first connecting terminal, and the second connecting terminal; and

one flexible wiring board so that the first connecting terminal and the second connecting terminal are formed on the one flexible wiring board, wherein said one flexible wiring board is arranged so that the first connecting terminal is situated on a lower surface of the semiconductor device and the second connecting terminal is situated on an upper surface of the semiconductor device.

As clarified above, the present invention enables to easily provide the semiconductor device of the MCP structure, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because it is possible to use a general-purpose semiconductor device for another semiconductor device described above, and because the first connecting terminal and the second connecting terminal are formed on the one flexible wiring board.

According to a sixth aspect of the present invention, in the semiconductor device in the previous aspects, said semiconductor chip is mounted on either or both the first wiring board and the second wiring board.

As clarified above, the present invention enables to achieve the cost reduction of the semiconductor device with minimizing the size of the semiconductor device, because two or more semiconductor chips are electrically connected on the wiring board described above. In addition, the present invention enables to achieve the cost reduction of the circuit board with minimizing the area of the circuit board that mounts the semiconductor device.

According to a seventh aspect of the present invention, in the semiconductor device in the sixth aspect, a concave portion for accommodating the semiconductor chip is included in either or both the first wiring board and the second wiring board.

As clarified above, the present invention enables to achieve small and thin making of the semiconductor device, and to achieve the cost reduction of the semiconductor device, because the first wiring board and the second wiring board are connected directly without using the joint material.

According to an eighth aspect of the present invention, the semiconductor device in the previous aspects, further comprises a flexible wiring board for connecting the first wiring board, on which the first connecting terminal is formed, to the second wiring board on which the second connecting terminal is formed.

As clarified above, the present invention enables to achieve reduction of man-hour of the work in the semiconductor package assembly process, because the first wiring board and second wiring board are connected beforehand with the flexible wiring board. In addition, the present invention enables to transform the first wiring board and the second wiring board into arbitrary shape, and to freely arrange two or more semiconductor chips on the first wiring board and the second wiring board.

According to a ninth aspect of the present invention, in the semiconductor device in the fifth aspect, said flexible wiring board includes an embossed concave portion for accommodating the semiconductor chip.

As clarified above, the present invention enables to achieve reduction of man-hour of the work in the semiconductor package assembly process, because of mounting the semiconductor chip on the flexible wiring board beforehand (for instance, with emboss taping). In addition, the present invention enables to prevent damage of the semiconductor chip, because one or two or more semiconductor chips are electrically connected on the concave portion of the flexible wiring board.

According to a tenth aspect of the present invention, in the semiconductor device in the previous aspects, said second connecting terminal is formed in a pitch array having an arrangement of n×m (n and m are natural numbers equal to or more than two), and said pitch array has a pitch of 1 mm or less, for electrically connecting the semiconductor device to another semiconductor device (for instance, a flash memory, a memory semiconductor device with built-in DRAM and SRAM).

As clarified above, the present invention enables to provide the semiconductor device as standard goods without individually manufacturing semiconductor devices of various amount of memory, because of mounting, in the laminated structure, the memory semiconductor device with built-in flash memory, DRAM, and SRAM on the semiconductor device (which is microcomputer with built-in flash memory, DSP, CPU, and programmable logic LSI, etc). That is, the present invention enables to provide semiconductor devices of various amount of memory with combining and using standard goods manufactured beforehand. Also, the present invention enables to easily develop cheap and general-purpose semiconductor devices, and to produce the semiconductor device of the multi-chip composition at a low price.

According to an eleventh aspect of the present invention, in the semiconductor device in the previous aspects, said first connecting terminal is formed in a first pitch array having an arrangement of n×m (n and m are natural numbers equal to or more than two), said second connecting terminal is formed in a second pitch array having the arrangement of n×m (n and m are natural numbers equal to or more than two), and said second pitch array has a pitch the same as that of the first pitch array.

As clarified above, the present invention enables to mount two or more memory semiconductor devices in the laminated structure, because of manufacturing the memory semiconductor device as the same structure described above. Here, the memory semiconductor device suggests another semiconductor device described above. In addition, the present invention enables to provide the bus-line in the laminated structure.

Also, it comes to use programmable logic LSI for consumer products and the cellular phone, because of corresponding increase of circuit scale of semiconductor device, intensification of development race of semiconductor device, and shortening of development period of semiconductor device. Therefore, the present invention enables to easily achieve the multi-chip structure of the semiconductor device, because of manufacturing the programmable logic LSI as the same structure described above, and using various IP and memory as another semiconductor device described above. In addition, the present invention enables to achieve great shortening of development period and cost reduction of development investment.

The present invention produces the effect of easily achieving the multi-chip structure of the semiconductor device, after the semiconductor device has been sealed, or the semiconductor device has been mounted on printed wiring board such as motherboard. Also, the present invention enables to easily change another semiconductor device mounted on the semiconductor device, after the semiconductor device has been sealed, or the semiconductor device has been mounted on printed wiring board such as motherboard.

Also, the present invention enables to mount various general-purpose semiconductor devices (for instance, CPU, DSP, DRAM, Flash memory, power supply, driver, custom LSI, analog IC, and electronic parts), with depending on needs, on the semiconductor device, after the semiconductor device, in which one or two or more semiconductor chips, and several connecting terminals taken out of the semiconductor chips, are included, with condition that the semiconductor chips and several connecting terminals are sealed with packaging materials, has been composed. Thus, the present invention enables to provide the multi-chip package (semiconductor device of MCP structure), with mounting another semiconductor device (for instance, High-speed CPU, Low power consumption CPU, Large capacity memory, Medium capacity memory, Small capacity memory), with depending on needs, on the semiconductor device.

That is, the present invention produces the effect of achieving the multi-chip structure of the semiconductor device, in the process of manufacturing the printed wiring board with depending on variations (for instance, High-level model, Middle-level model, Low-level model), and produces the effect of achieving efficiency improvement of product development, and cost reduction in the manufacturing process.

Also, it is necessary to inspect each semiconductor chip that is component of semiconductor device composed of MCP structure. However, it is very likely that the yield of the semiconductor device composed of MCP structure deteriorates compared with the semiconductor device composed of one chip, because it is impossible to inspect all functions of the semiconductor chip. The present invention produces the effect of improving the yield described above, and the productivity of semiconductor devices, by using general-purpose semiconductor device, which has been completed to inspect, as another semiconductor device mounted on the semiconductor device.

Also, the present invention produces the effect of achieving speed-up of electric signal process, and high-density mounting, with making the wiring distance between semiconductor devices the shortest. In addition, the present invention produces the effect of reducing malfunction because of noise mixing and signal delay, with making the wiring distance between semiconductor devices the shortest. As a result, the present invention provides achieving to secure the quality.

Also, the present invention produces the effect of achieving to decrease drive current, and to decrease power consumption, with making the wiring distance between semiconductor devices the shortest.

### BRIEF DESCRIPTION OF DRAWINGS

FIGS. 1(a) and 1(b) are views showing a semiconductor device according to a first embodiment of the present invention, wherein FIG. 1(a) is a plan view of the semiconductor device, and FIG. 1(b) is a cross sectional view thereof taken along a line 1(b)-1(b) in FIG. 1(a);

FIG. 2 is a cross sectional view of a semiconductor device according to a second embodiment of the present invention;

FIG. 3 is a cross sectional view of a semiconductor device according to a third embodiment of the present invention;

FIG. 4 is a cross sectional view of a semiconductor device according to a fourth embodiment of the present invention;

FIG. 5 is a cross sectional view of a semiconductor device according to a fifth embodiment of the present invention;

FIG. 6 is a cross sectional view of a semiconductor device according to a sixth embodiment of the present invention;

FIG. 7 is a cross sectional view of a semiconductor device according to a seventh embodiment of the present invention;

FIG. 8 is a cross sectional view of a semiconductor device according to am eighth embodiment of the present invention;

FIG. 9 is a cross sectional view of a semiconductor device according to a ninth embodiment of the present invention; and

FIG. 10 is a cross sectional view of a semiconductor device according to a tenth embodiment of the present invention.

### DETAILED DESCRIPTION OF THE PREFERRED EMBODIMENTS

Hereunder, embodiments of the present invention will be described with reference to the accompanying drawings. The invention is not limited to the embodiments.

### First Embodiment

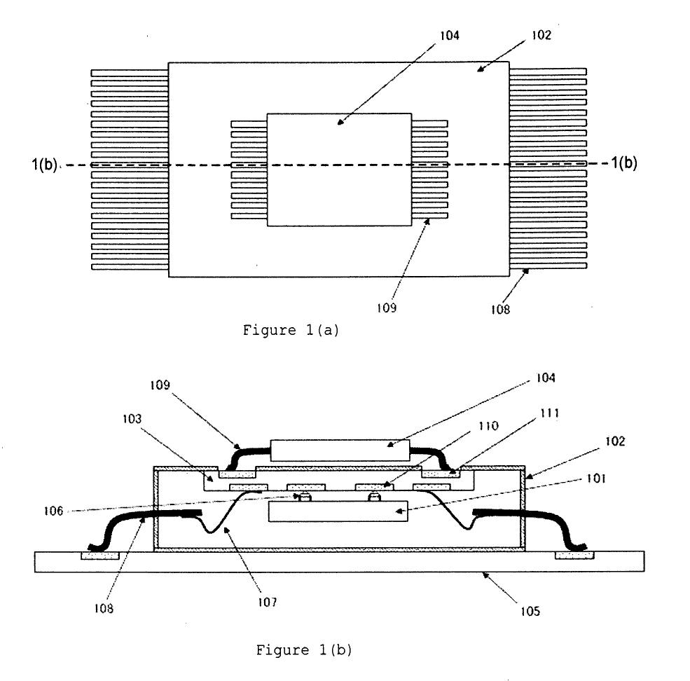

FIG. 1 shows top view of the semiconductor device, and cross section of the semiconductor device, for carrying out “First embodiment” of the present invention.

In FIG. 1, the semiconductor device for programmable logic or operation processing comprises:

the semiconductor chip 101;

the first connecting terminal 108 for electrically connecting the semiconductor device to the printed circuit board 105 on which the semiconductor device is to be mounted;

the second connecting terminal 111 for electrically connecting the semiconductor device to another semiconductor device 104; and

the packaging material 102 for sealing the semiconductor chip 101, the first connecting terminal 108, and the second connecting terminal 111;

wherein the first connecting terminal 108 is formed of the lead frame, and the second connecting terminal 111 is formed on the wiring board 103.

Here, the semiconductor device has the structure of forming the Pad 111, to electrically connect to another semiconductor device 104, as the second connecting terminal, on the upper of the wiring board 103 sealed with packaging materials 102. Also, the semiconductor device has the structure of forming the Pad 110, to electrically connect to the semiconductor chip 101, on the under of the wiring board 103, wherein the Pad 110 is electrically connected to the semiconductor chip 101 through the bump 106. Also, the semiconductor device has the structure of forming the lead frame 108, to electrically connect the semiconductor chip 101 and the printed circuit board 105, as the first connecting terminal, wherein the lead frame 108 is electrically connected to the semiconductor chip 101 or the wiring board 103 through the bonding wire 107.

Also, the semiconductor device has the structure of mounting the semiconductor chip 101 on the under of the wiring board 103, and mounting another semiconductor device 104 on the upper of the wiring board 103. Thereby, the present invention enables to achieve speed-up of electric signal process, and high-density mounting, because of making the wiring distance between semiconductor devices the shortest.

Also, the semiconductor device has the structure of forming the Pad 111 as the second connecting terminal, wherein the Pad 111 is electrically connected to another semiconductor device 104 through lead frame 109. Thereby, the present invention enables to achieve mounting another semiconductor device 104 on the semiconductor device in the process of manufacturing the printed wiring board.

As clarified above, the present invention enables to easily achieve the multi-chip structure of the semiconductor device, after the semiconductor device has been sealed, or the semiconductor device has been mounted on printed wiring board such as motherboard, with condition that the second connecting terminal 111 of the semiconductor device is connected to another semiconductor device 104.

Also, the present invention enables to minimize the mounting area of the circuit, to mount two or more semiconductor devices in the laminated structure, by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because of using a general-purpose semiconductor device for another semiconductor device. In addition, the present invention enables to achieve cost reduction of materials, because the first connecting terminal is composed of the lead frame.

### Second Embodiment

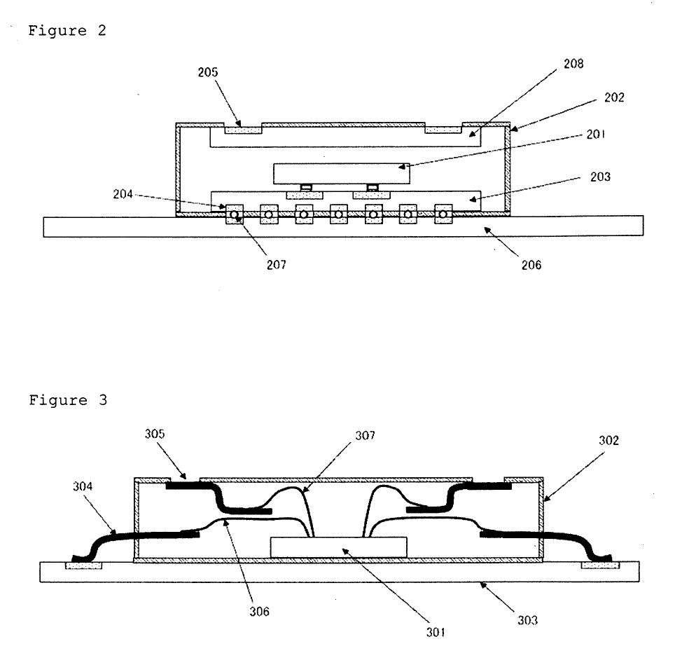

FIG. 2 shows a cross section of the semiconductor device, for carrying out “Second embodiment” of the present invention.

In FIG. 2, the semiconductor device for programmable logic or operation processing comprises:

the semiconductor chip 201;

the first connecting terminal 204 for electrically connecting the semiconductor device to the printed circuit board 206 on which the semiconductor device is mounted;

the second connecting terminal 205 for electrically connecting the semiconductor device to another semiconductor device; and

the packaging material 202 for sealing the semiconductor chip 201, the first connecting terminal 204, and the second connecting terminal 205;

wherein the first connecting terminal 204 is formed on the first wiring board 203, and the second connecting terminal 205 is formed on the second wiring board 208.

Here, the semiconductor device has the structure of forming the Pad 204 as the first connecting terminal, on the first wiring board 203, wherein the Pad 204 is electrically connected to the printed circuit board 206 through the bump 207. Also, the semiconductor device has the structure of forming the Pad 205, to electrically connect to another semiconductor device, as the second connecting terminal, on the second wiring board 208.

Thus, the present invention enables to achieve mounting the semiconductor chip 201 on the first wiring board 203 or the second wiring board 208, through the bump 207 or bonding wire, wherein the first wiring board 203 and the second wiring board 208 are electrically connected. Thereby, the semiconductor chip 201 is electrically connected to the printed circuit board 206 or another semiconductor device, with securing the quality, because the semiconductor chip 201 is connected to the first wiring board 203 (securing the quality) or the second wiring board 208 (securing the quality) through the bump 207 or bonding wire. As a result, the present invention enables to easily achieve the multi-chip structure of the semiconductor device with securing the quality.

As clarified above, the present invention enables to easily achieve the multi-chip structure of the semiconductor device, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit, to mount two or more semiconductor devices in the laminated structure, by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because of using a general-purpose semiconductor device for another semiconductor device described above.

### Third Embodiment

FIG. 3 shows a cross section of the semiconductor device, for carrying out “Third embodiment” of the present invention.

In FIG. 3, the semiconductor device for programmable logic or operation processing comprises:

the semiconductor chip 301;

the first connecting terminal 304 for electrically connecting the semiconductor device to the printed circuit board 303 on which the semiconductor device is mounted;

the second connecting terminal 305 for electrically connecting the semiconductor device to another semiconductor device; and

the packaging material 302 for sealing the semiconductor chip 301, the first connecting terminal 304, and the second connecting terminal 305;

wherein the first connecting terminal 304 is formed of the first lead frame, and the second connecting terminal 305 is formed of the second lead frame.

Here, the semiconductor device has the structure of forming the lead frame 304 as the first connecting terminal, wherein and the lead frame 304 is electrically connected to the semiconductor chip 301 through the bonding wire 306, and the lead frame 304 is electrically connected to the printed circuit board 303. Also, the semiconductor device has the structure of forming the lead frame 305, to electrically connect to another semiconductor device, as the second connecting terminal, wherein and the lead frame 305 is electrically connected to the semiconductor chip 301 through the bonding wire 307.

As clarified above, the present invention enables to easily achieve the multi-chip structure of the semiconductor device, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit, to mount two or more semiconductor devices in the laminated structure, by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because of using a general-purpose semiconductor device for another semiconductor device described above. In addition, the present invention enables to achieve cost reduction of materials, because the first connecting terminal and the second connecting terminal are composed of lead frames.

### Fourth Embodiment

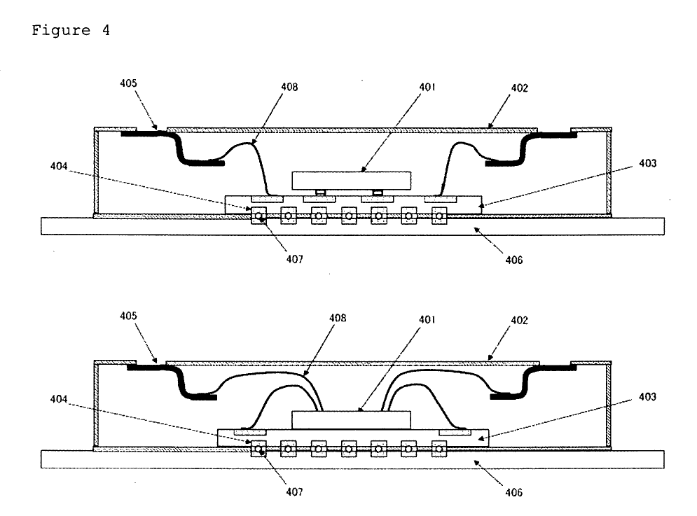

FIG. 4 shows a cross section of the semiconductor device, for carrying out “Fourth embodiment” of the present invention.

In FIG. 4, the semiconductor device for programmable logic or operation processing comprises:

the semiconductor chip 401;

the first connecting terminal 404 for electrically connecting the semiconductor device to the printed circuit board 406 on which the semiconductor device is mounted;

the second connecting terminal 405 for electrically connecting the semiconductor device to another semiconductor device; and

the packaging material 402 for sealing the semiconductor chip 401, the first connecting terminal 404, and the second connecting terminal 405;

wherein the first connecting terminal 404 is formed on the wiring board 403, and the second connecting terminal 405 is composed of the lead frame.

Here, in FIG. 4, the semiconductor device has the structure of forming the Pad 404 as the first connecting terminal, on the wiring board 403, wherein the Pad 404 is electrically connected to the printed circuit board 406 through the bump 407. Also, the semiconductor device has the structure of forming the lead frame 405 as the second connecting terminal, wherein and the lead frame 405 is electrically connected to the wiring board 403 through the bonding wire 408, and the semiconductor chip 401 is electrically connected to the wiring board 403 through the bump.

Also, in FIG. 4, the semiconductor device has the structure of forming the lead frame 405, to electrically connect to another semiconductor device, as the second connecting terminal, wherein and the lead frame 405 is electrically connected to the semiconductor chip 401 through the bonding wire 408, and the semiconductor chip 401 is electrically connected to the wiring board 403 through the bonding wire.

As clarified above, the present invention enables to easily achieve the multi-chip structure of the semiconductor device, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit, to mount two or more semiconductor devices in the laminated structure, by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because of using a general-purpose semiconductor device for another semiconductor device described above. In addition, the present invention enables to achieve cost reduction of materials, because the second connecting terminal is composed of lead frames.

### Fifth Embodiment

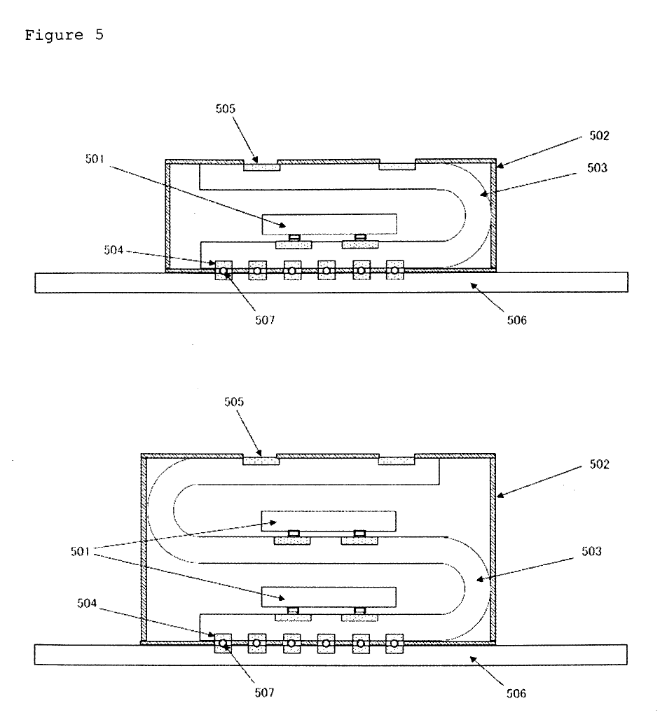

FIG. 5 shows a cross section of the semiconductor device, for carrying out “Fifth embodiment” of the present invention.

In FIG. 5, The semiconductor device for programmable logic or operation processing comprises:

the semiconductor chip 501;

the first connecting terminal 504 for electrically connecting the semiconductor device to the printed circuit board 506 on which the semiconductor device is mounted;

the second connecting terminal 505 for electrically connecting the semiconductor device to another semiconductor device;

the packaging material 502 for sealing the semiconductor chip 501, the first connecting terminal 504, and the second connecting terminal 505; and

one flexible wiring board 503 so that the first connecting terminal 504 and the second connecting terminal 505 are formed on the one flexible wiring board 503, wherein said one flexible wiring board 503 is arranged so that the first connecting terminal 504 is situated on a lower surface of the semiconductor device and the second connecting terminal 505 is situated on an upper surface of the semiconductor device.

Here, in FIG. 5, the semiconductor device has the structure of forming the Pad 504 as the first connecting terminal, on the flexible wiring board 503, wherein the Pad 504 is electrically connected to the printed circuit board 506 through the bump 507. Also, the semiconductor device has the structure of forming the Pad 505, to electrically connect to another semiconductor device, as the second connecting terminal, on the flexible wiring board 503, wherein the first connecting terminal 504 and the second connecting terminal 505 are formed on one flexible wiring board 503.

Also, in FIG. 5, the semiconductor device has the structure of forming the Pad 504 as the first connecting terminal in one surface of the flexible wiring board 503, and forming the Pad 505 as the second connecting terminal in opposite surface of the flexible wiring board 503.

As clarified above, the present invention enables to easily achieve the multi-chip structure of the semiconductor device, after the semiconductor device has been sealed, or the semiconductor device has been mounted on printed wiring board such as motherboard, with condition that the second connecting terminal of the semiconductor device is connected to another semiconductor device described above.

Also, the present invention enables to minimize the mounting area of the circuit, to mount two or more semiconductor devices in the laminated structure, by using the general-purpose semiconductor device, and to make the wiring distance between semiconductor devices the shortest. As a result, the present invention enables to achieve to secure the quality and the performance of an electric signal, to decrease power consumption, and to decrease an unnecessary radiation.

Also, the present invention enables to achieve great shortening of development period and cost reduction of development investment, because of using a general-purpose semiconductor device for another semiconductor device described above, and forming the first connecting terminal and the second connecting terminal on one flexible wiring board.

### Sixth Embodiment

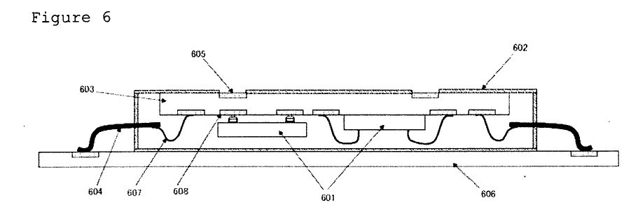

FIG. 6 shows a cross section of the semiconductor device, for carrying out “Sixth embodiment” of the present invention. In FIG. 6, based on “First embodiment (FIG. 1)”, it is a feature of the semiconductor device that one or two or more semiconductor chips 601 are mounted on the wiring board 603.

Here, the semiconductor device has the structure of forming the Pad 605, to electrically connect to another semiconductor device, as the second connecting terminal, on the upper surface of the wiring board 603. Also, the semiconductor device has the structure of forming the Pad 608, to electrically connect to one or two or more semiconductor chips 601, on the under surface of the wiring board 603.

Also, the semiconductor device has the structure of forming the lead frame 604 as the first connecting terminal, wherein and the lead frame 604 is electrically connected to the wiring board 603 through the bonding wire 607, and the semiconductor chips 601 is electrically connected to the wiring board 603 through the bump or bonding wire.

As clarified above, the present invention enables to achieve the cost reduction of the semiconductor device with minimizing the size of the semiconductor device, because two or more semiconductor chips are electrically connected on the wiring board described above. In addition, the present invention enables to achieve the cost reduction of the circuit board with minimizing the area of the circuit board that mounts the semiconductor device.

### Seventh Embodiment

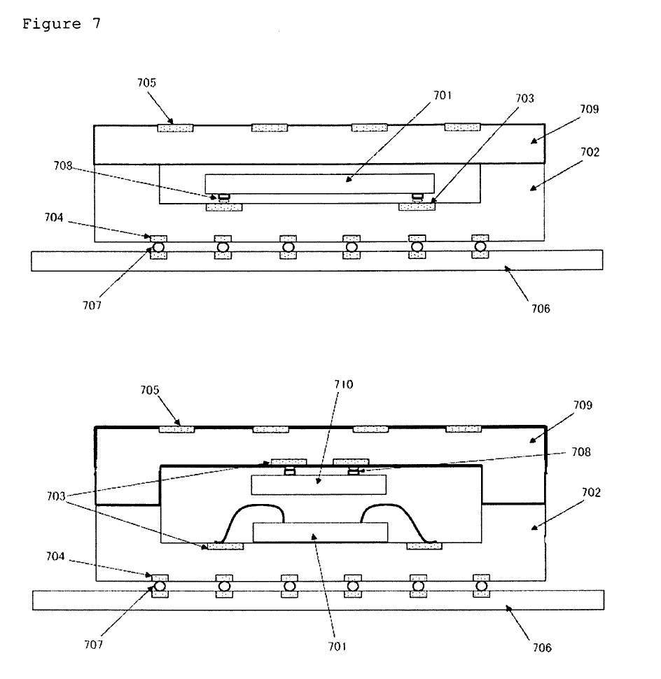

FIG. 7 shows a cross section of the semiconductor device, for carrying out “Seventh embodiment” of the present invention. In FIG. 7, based on “Second embodiment (FIG. 2)”, it is a feature of the semiconductor device that the concave portion for accommodating the semiconductor chip 701 is included in either or both the first wiring board 702 and the second wiring board 709.

Here, in FIG. 7, the semiconductor device has the structure of forming the concave portion, in which the semiconductor chip 701 are stored, on the first wiring board 702, and forming the Pad 703, wherein the semiconductor chips 701 is electrically connected to the Pad 703. Also, the semiconductor device has the structure of mounting the second wiring board 709 (formed second connecting terminal 705) on the first wiring board 702, in which the concave portion has been formed, wherein the first wiring board 702 and the second wiring board 709 are electrically connected.

Also, the semiconductor device has the structure of forming the Pad 704 as the first connecting terminal on the under surface of the first wiring board 702, wherein the Pad 704 and the printed wiring board 706 are electrically connected through the bump 707. Also, the semiconductor device has the structure of forming the Pad 705, to electrically connect to another semiconductor device, as the second connecting terminal, on the upper surface of the second wiring board 709.

Here, in FIG. 7, the semiconductor device has the structure of forming the concave portion, in which the semiconductor chips 701 and the semiconductor chips 710 are stored, on both of the first wiring board 702 and the second wiring board 709, wherein the semiconductor chips 701 is electrically connected to the first wiring board 702 through the bump or bonding wire, and the semiconductor chips 710 is electrically connected to the second wiring board 709 through the bump or bonding wire.

As clarified above, the present invention enables to achieve great shortening of development period, and to achieve the cost reduction of the semiconductor device, because the first wiring board 702 and second wiring board 709 are connected directly without using the joint material. Also, the present invention enables to achieve small and thin making of the semiconductor device, and to achieve the cost reduction of the semiconductor device with minimizing the size of the semiconductor device.

### Eighth Embodiment

FIG. 8 shows cross section of the semiconductor device, for carrying out “Eighth embodiment” of the present invention.

In FIG. 8, based on “Second embodiment (FIG. 2)” or “Seventh embodiment (FIG. 7)”, it is a feature of the semiconductor device that the semiconductor device further comprises the flexible wiring board 809 for connecting the first wiring board 803, on which the first connecting terminal 804 is formed, to the second wiring board 808 on which the second connecting terminal 805 is formed.

As clarified above, the present invention enables to achieve reduction of man-hour of the work in the semiconductor package assembly process, because the first wiring board 803 and second wiring board 808 are connected beforehand with the flexible wiring board 809. In addition, the present invention enables to transform the first wiring board 803 and the second wiring board 808 into arbitrary shape, and to freely arrange two or more semiconductor chips on the first wiring board 803 and the second wiring board 808.

### Ninth Embodiment

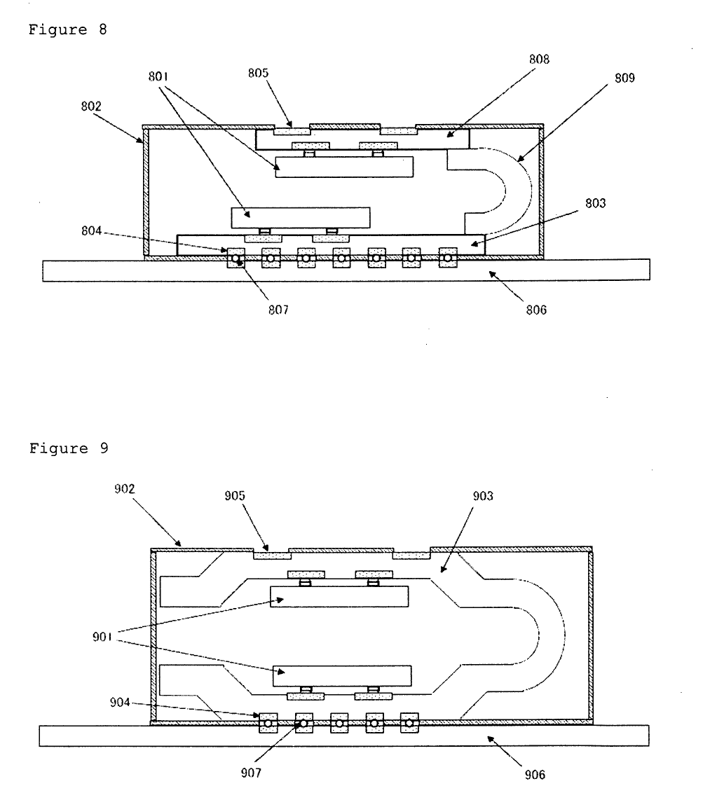

FIG. 9 shows a cross section of the semiconductor device, for carrying out “Ninth embodiment” of the present invention. In FIG. 9, based on “Fifth embodiment (FIG. 5)”, it is a feature of the semiconductor device that the flexible wiring board 903 includes the embossed concave portion for accommodating the semiconductor chip 901.

As clarified above, the present invention enables to achieve reduction of man-hour of the work in the semiconductor package assembly process, because of mounting the semiconductor chip 901 on the flexible wiring board 903 beforehand (for instance, with emboss taping). In addition, the present invention enables to prevent damage of the semiconductor chip 901, because one or two or more semiconductor chips are electrically connected on the concave portion of the flexible wiring board 903.

### Tenth Embodiment

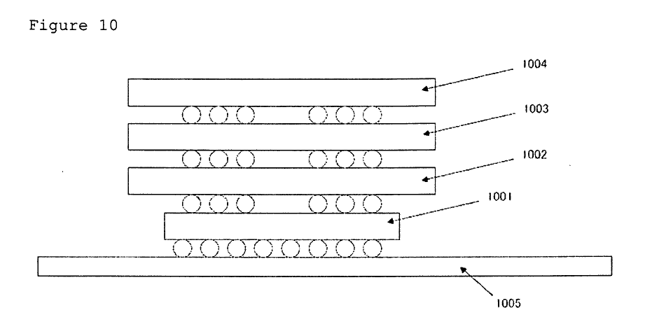

FIG. 10 shows a cross section of the semiconductor device, for carrying out “Tenth embodiment” of the present invention. In FIG. 10, it is a feature of the semiconductor device that the second connecting terminal is formed in a pitch array having an arrangement of n×m (n and m are natural numbers equal to or more than two), and the pitch array has a pitch of 1 mm or less, for electrically connecting the semiconductor device 1001 to another semiconductor device 1002 (for instance, a flash memory, a memory semiconductor device with built-in DRAM and SRAM).

As clarified above, the present invention enables to provide the semiconductor device as standard goods without individually manufacturing semiconductor devices of various amount of memory, because of mounting, in the laminated structure, the memory semiconductor device with built-in flash memory, DRAM, and SRAM on the first semiconductor device 1001 (which is microcomputer with built-in flash memory, DSP, CPU, and programmable logic LSI, etc). That is, the present invention enables to provide semiconductor devices of various amount of memory with combining and using standard goods manufactured beforehand. Here, the pitch array and the pitch width are formed in accordance with the standard of JEITA (Japan Electronics and Information Technology Industries Association), or EIA (Electronic Industries Alliance), or ISO (International Organization for Standardization).

Recently, the semiconductor devices of SOC and MCP composition, with built-in flash memory, DRAM, and SRAM, are used in various fields. The cost of these semiconductor devices is higher than the cost of the semiconductor device of the present invention. That is, 50% to 80% of the chip area of SOC is often occupied with the memory, and increase of the chip area of SOC, in which the chip unit price is higher than the price of the general-purpose semiconductor chip, will remarkably weaken competitive edge. Also, in the semiconductor device of the MCP structure, it is necessary to obtain the memory chip of the bare chip, and it is generally difficult to obtain them. Therefore, the special MCP package matched to each manufacturer is needed, because interchangeability of the chip size and the connecting terminals doesn't exist between manufacturers. That is a big factor to raise the cost, because the competition between manufacturers doesn't exist.

As clarified above, the present invention enables to easily develop cheap and general-purpose semiconductor devices, and to provide the semiconductor device of the multi-chip composition at a low price.

Also, in FIG. 10, it is a feature of the semiconductor device that the first connecting terminal is formed in a first pitch array having an arrangement of n×m (n and m are natural numbers equal to or more than two), the second connecting terminal is formed in a second pitch array having the arrangement of n×m (n and m are natural numbers equal to or more than two), and the second pitch array has a pitch the same as that of the first pitch array.

As clarified above, the present invention enables to mount two or more memory semiconductor devices, in the laminated structure, on the first semiconductor device 1001, because of manufacturing the memory semiconductor device 1002 as the same structure described above. In addition, the present invention enables to produce the bus-line in the laminated structure. FIG. 10 shows the multi-chip structure with mounting the second semiconductor device 1002 on the first semiconductor device 1001, mounting the 3rd semiconductor device 1003 on the second semiconductor device 1002, and mounting the 4th semiconductor device 1004 on the 3rd semiconductor device 1003.

Recently, programmable logic LSI (for instance, FPGA, and PLD) has come to be used for consumer products and cellular phones, in accordance with increase of circuit scale of semiconductor device, intensification of development race of semiconductor device, and shortening of development period. However, there is a problem that the chip area of the programmable logic LSI is tens of times as large as the chip area of the semiconductor chip used with SOC and MCP, and the cost of the programmable logic LSI is higher than the cost of the semiconductor chip used with SOC and MCP. Also, It is advanced to build various IP and the memory into the programmable logic LSI, in accordance with high function of the LSI. As a result, there is a problem that we cannot avoid further increase of the chip area of the programmable logic LSI and sudden rise of the price of the LSI.

Then, the present invention proposes manufacturing the programmable logic LSI with the structure of the semiconductor device described above. Also, the present invention enables to easily achieve the multi-chip structure of the semiconductor device, with mounting the various IP and the memory chip, as another semiconductor device, on the semiconductor device described above. As a result, the present invention enables to achieve great shortening of development period and cost reduction of development investment.

Recently, semiconductor process and circuit element for particular applications are used in various fields, with high function and high performance of LSI. And the technology, with which the entire system is constructed by using LSI, progresses greatly to achieve high-density mounting and cost reduction. The present invention discloses the technology to enable to easily provide the semiconductor device of the MCP structure using the general-purpose semiconductor device, and to enable to freely mount the semiconductor chip or the semiconductor device after the MCP package has been sealed.

By using the technology of the present invention, it is possible to mount various general-purpose semiconductor devices (for instance, CPU, DSP, DRAM, Flash memory, power supply, driver, custom LSI, analog IC, and electronic parts), with depending on needs, on the semiconductor package, after the semiconductor device, in which one or two or more semiconductor chips, and several connecting terminals taken out of the semiconductor chips, are included, with condition that the semiconductor chips and several connecting terminals are sealed with packaging materials, has been composed.

That is, the present invention produces the effect of achieving the multi-chip structure of the semiconductor device, in the process of manufacturing the printed wiring board with depending on variations (for instance, High-level model, Middle-level model, Low-level model), and produces the effect of achieving efficiency improvement of product development, and cost reduction in the manufacturing process.

Also, it is very likely that the yield of the semiconductor device composed of MCP structure deteriorates compared with the semiconductor device composed of one chip, because it is impossible to inspect all functions of the semiconductor chip. Then, by using the technology of the present invention, it is possible to improve the yield described above, and the productivity of semiconductor devices, using general-purpose semiconductor device, which has been completed to inspect, as another semiconductor device mounted on the semiconductor device.

Also, by using the technology of the present invention, it is possible to achieve speed-up of electric signal process, and high-density mounting, with making the wiring distance between semiconductor devices the shortest. In addition, it is possible to reduce malfunction because of noise mixing and signal delay, with making the wiring distance between semiconductor devices the shortest, and to achieve to secure the quality. Also, it is possible to achieve to decrease drive current, and to decrease power consumption, with making the wiring distance between semiconductor devices the shortest.

What is claimed is:

1. A semiconductor device for programmable logic or operation processing, comprising:
a semiconductor chip;
a first connecting terminal for electrically connecting the semiconductor device to a printed circuit board on which the semiconductor device is to be mounted;
a second connecting terminal for electrically connecting the semiconductor device to another semiconductor device; and
a packaging material for sealing the semiconductor chip, the first connecting terminal, and the second connecting terminal.

2. The semiconductor device according to claim 1, wherein said first connecting terminal is formed of a first lead frame.

3. The semiconductor device according to claim 1, further comprising a first wiring board, said first connecting terminal being formed on the first wiring board.

4. The semiconductor device according to claim 1, wherein said second connecting terminal is formed of a second lead frame.

5. The semiconductor device according to claim 1, further comprising a second wiring board, said second connecting terminal being formed on the second wiring board.

6. The semiconductor device according to claim 1, further comprising one flexible wiring board so that the first connecting terminal and the second connecting terminal are formed on the one flexible wiring board, said one flexible wiring board being arranged so that the first connecting terminal is situated on a lower surface of the semiconductor device and the second connecting terminal is situated on an upper surface of the semiconductor device.

7. The semiconductor device according to claim 3, wherein said semiconductor chip is mounted on the first wiring board.

8. The semiconductor device according to claim 5, wherein said semiconductor chip is mounted on the second wiring board.

9. The semiconductor device according to claim 7, wherein said first wiring board includes a first concave portion for accommodating the semiconductor chip.

10. The semiconductor device according to claim 8, wherein said second wiring board includes a second concave portion for accommodating the semiconductor chip.

11. The semiconductor device according to claim 3, further comprising a flexible wiring board for connecting the first wiring board to a second wiring board on which the second connecting terminal is formed.

12. The semiconductor device according to claim 5, further comprising a flexible wiring board for connecting the second wiring board to a first wiring board on which the first connecting terminal is formed.

13. The semiconductor device according to claim 6, wherein said flexible wiring board includes an embossed concave portion for accommodating the semiconductor chip.

14. The semiconductor device according to claim 1, wherein said second connecting terminal is formed in a pitch array having an arrangement of n×m (n and m are natural numbers equal to or more than two), said pitch array having a pitch of 1 mm or less.

15. The semiconductor device according to claim 1, wherein said first connecting terminal is formed in a first pitch array having an arrangement of n×m (n and m are natural numbers equal to or more than two), said second connecting terminal being formed in a second pitch array having the arrangement of n×m (n and m are natural numbers equal to or more than two), said second pitch array having a pitch the same as that of the first pitch array.
